(19) United States
(12) Patent Application Publication
(10) Pub. No.: US 2026/0231776 A1
(43) Pub. Date: Aug. 6, 2026

(54) PACKAGE DEVICE

(71) Applicant: Innolux Corporation, Miaoli County (TW)

(72) Inventors: Chin-Ming Huang, Miaoli County (TW); Mei-Yen Chen, Miaoli County (TW)

(73) Assignee: Innolux Corporation, Miaoli County (TW)

(21) Appl. No.: 19/438,645

(22) Filed: Jan. 1, 2026

Related U.S. Application Data
(60) Provisional application No. 63/753,962, filed on Feb. 5, 2025.

(30) Foreign Application Priority Data
Sep. 24, 2025 (CN) 202511372546.4

(51) Int. Cl. H10W 42/20; H10W 46/00; H10W 70/63; H10W 74/15; H10W 90/00

(52) U.S. Cl. CPC H10W 42/265; H10W 46/301; H10W 46/607; H10W 70/635; H10W 74/15; H10W 90/724

(57) ABSTRACT

A package device includes a substrate and a metal structure. The substrate has a first region and a second region surrounding the first region. The metal structure is disposed on the substrate and includes a signal pattern and a shielding component. The shielding component includes a first shielding component and a second shielding component. The signal pattern and the first shielding component are disposed in the first region, while the second shielding component is disposed in the second region. The first shielding component and the second shielding component are isolated from each other. Along a direction perpendicular to a normal direction of the substrate, a dimension of the second shielding component gradually increases with increasing distance from an edge of the substrate.

### CROSS-REFERENCE TO RELATED APPLICATION

This application claims the priority benefit of U.S. Provisional Application No. 63/753,962, filed on February 05, 2025 and China Application No. 202511372546.4, filed on September 24, 2025. The entirety of each of the above-mentioned patent applications is hereby incorporated by reference herein and made a part of this specification.

### BACKGROUND

### Technical Field

The present disclosure relates to a semiconductor device, and particularly relates to a package device having electrostatic protection.

### Related Art

ESD often causes damage to package devices, rendering the products unable to operate normally. For example, Redistribution Layer (RDL) may be developed as ultra-fine pitch electronic devices for the increasing number of input/output (I/O) pins in today's advanced packaging technology. However, because the transmission circuits of the RDL are fine and long, an issue of sensitivity to electrostatic ions may be encountered. Therefore, how to improve the yield or reliability of package devices has become one of the pressing issues to be addressed.

### SUMMARY

The present disclosure is directed to a package device having better electrostatic protection, which may improve yield or reliability.

In an embodiment of the present disclosure, a package device includes a substrate and a metal structure. The substrate has a first region and a second region surrounding the first region. The metal structure is disposed on the substrate and includes a signal pattern and a shielding component. The shielding component includes a first shielding component and a second shielding component. The signal pattern and the first shielding component are disposed in the first region, and the second shielding component is disposed in the second region. The first shielding component and the second shielding component are isolated from each other. Along a direction perpendicular to a normal direction of the substrate, a dimension of the second shielding component gradually increases with increasing distance from an edge of the substrate.

### BRIEF DESCRIPTION OF THE DRAWINGS

FIG. 1 is a top view of a package device according to an embodiment of the present disclosure.

FIGS. 2 to 5 are top views of multiple different implementation aspects of region A in FIG. 1.

FIG. 6 is a top view of a package device according to another embodiment of the present disclosure.

FIG. 7 is a cross-sectional view taken along line I-I in FIG. 6.

FIG. 8 is a top view of the redistribution layer structure or glass through hole substrate in FIG. 6.

FIG. 9 is a top view of the electronic unit in FIG. 6.

FIG. 10 is a cross-sectional view of a package device according to another embodiment of the present disclosure.

### DESCRIPTION OF THE EMBODIMENTS

In the following specification and claims, words such as "containing" and "comprising" are open-ended words, which should be interpreted as "including but not limited to...".

In addition, relative terms such as "below" or "bottom portion" and "above" or "top portion" may be used in the embodiments to describe the relative relationship between an element and another element in the drawings. It should be understood that if a device in the drawings is flipped upside down, elements described as "below" will become elements described as "above".

In some embodiments of the disclosure, when a component or film layer is referred to “on”, “connection”, “bonding” and “joining”, another component or film layer, unless specifically defined, may refer to two structures that are directly in contact or may also refer to two structures that are not directly (indirectly) in contact, wherein there is another structure provided between the two structures. Furthermore, the term "coupling" includes the transfer of energy between two structures through means of direct or indirect electrical connection or the transfer of energy between two separate structures by means of mutual induction.

The terms "about", "equal to", "equivalent" or "same", "substantially", or "roughly" are generally interpreted as within 20% of a given value or range, or interpreted as within 10%, 5%, or 0.5% of the given value or range.

In the disclosure, the definition of roughness judgment may be observed by the SEM or the transmission electron microscope (TEM), etc, observing the surface undulation condition under appropriate magnification, and taking a unit length (for example, 10μm) sample to compare the undulation condition as the roughness range. Here, "appropriate magnification" means that at least one surface may have a roughness (Rz) or an average roughness (Ra) of at least 10 peaks and valleys visible under the field of view of such a magnification.

As used herein, the terms "film" and/or "layer" may refer to any continuous or discontinuous structure and material.

Although the terms first, second, third... may be used to describe various constituent elements, the constituent elements are not limited by the terms. The terms are only used to distinguish a single constituent element from other constituent elements in the specification.

The electronic device of the present disclosure may include a power module, semiconductor device, semiconductor package device, display device, antenna device, sensing device, light-emitting device, or splicing device, but is not limited thereto. The electronic device may include a bendable electronic device. According to embodiments of the present disclosure, the provided manufacturing method of the electronic device may be applied to, for example, wafer-level package (WLP) or panel-level package (PLP) processes, and may adopt chip first processes or chip last/RDL first processes. The electronic device referred to in the present disclosure may include System on Package (SoC), System in Package (SiP), Antenna in package (AiP), Co-Packaged Optics (CPO), or combinations thereof, but is not limited thereto.

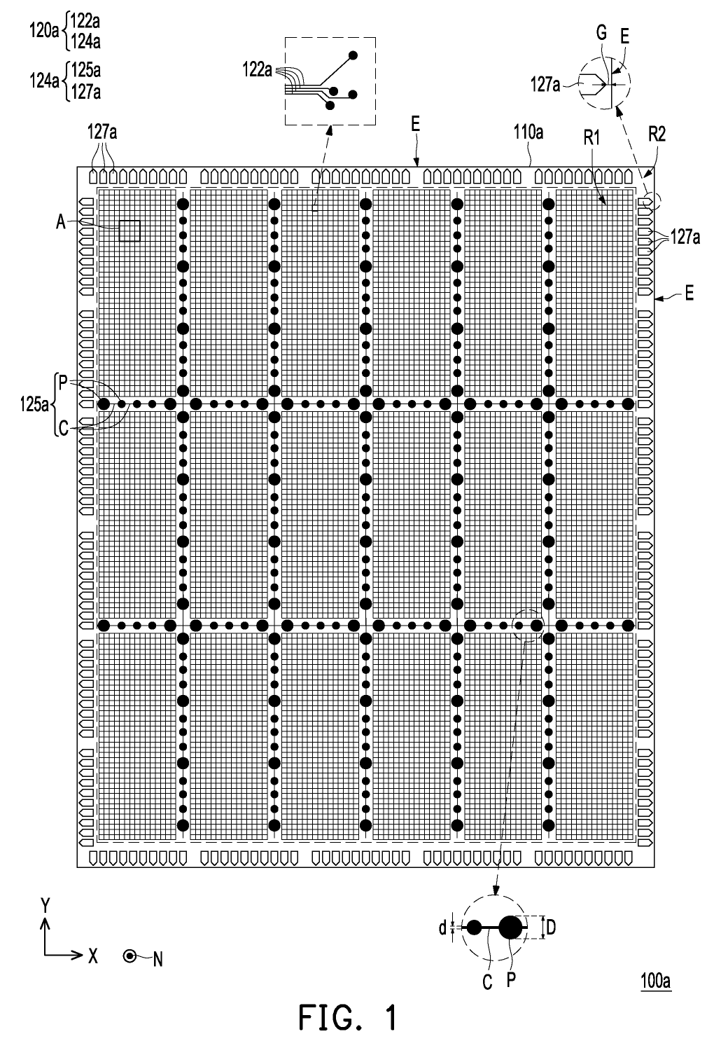

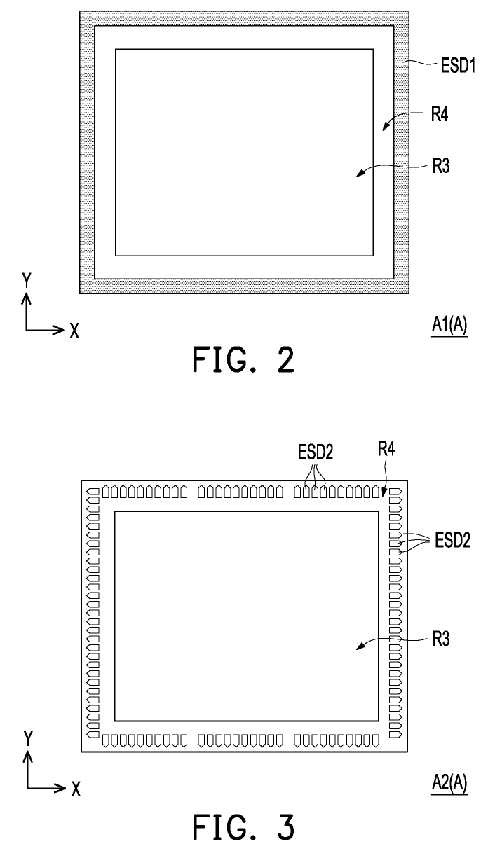

FIG. 1 is a top view schematic diagram of a package device according to an embodiment of the present disclosure. FIG. 2 to FIG. 5 are top view schematic diagrams of multiple different implementation aspects of region A in FIG. 1. Please refer to FIG. 1, in this embodiment, the package device 100a includes a substrate 110a and a metal structure 120a. The substrate 110a has a first region R1 and a second region R2 surrounding the first region R1. The metal structure 120a is disposed on the substrate 110a, and includes a signal pattern 122a and a shielding component 124a. The shielding component 124a includes a first shielding component 125a and a second shielding component 127a. The signal pattern 122a and the first shielding component 125a are disposed in the first region R1, while the second shielding component 127a is disposed in the second region R2. The first shielding component 125a and the second shielding component 127a are isolated from each other.

In one embodiment, the material of the substrate 110a is, for example, Polyimide, PSPI, glass, silicon substrate, or other suitable substrate materials. In one embodiment, the substrate 110a is, for example, an interposer substrate, redistribution substrate, circuit board, or carrier. In one embodiment, the first region R1 of the substrate 110a may be regarded as a component arrangement region, while the second region R2 of the substrate 110a may be regarded as a peripheral region. In one embodiment, the first region R1 is, for example, rectangular, while the second region R2 is, for example, annular. In one embodiment, the region of the first region R1 is larger than the region of the second region R2.

Furthermore, the signal pattern 122a of the metal structure 120a may be, for example, circuits, conductive through holes, conductive blind holes, pads, or combinations thereof. In one embodiment, the signal pattern 122a may be, for example, a redistribution structure layer, which may include at least one dielectric layer and at least one metal layer alternately stacked along the normal direction N of the substrate 110a to redistribute circuits and/or enhance circuit fan-out or fan-in region. In one embodiment, in transmission lines within the redistribution structure layer, ESD diodes (for example, Back-to-Back Die, BBD) may serve as voltage clamps to prevent fine traces from being damaged by ESD.

The shielding component 124a of the metal structure 120a has the effect of shielding electrostatic, wherein the shielding component 124a does not have electrical properties and may be regarded as a dummy pattern. The first shielding component 125a of the shielding component 124a and the signal pattern 122a are located in the first region R1 of the substrate 110a, wherein the first shielding component 125a may surround the signal pattern 122a. Here, "one component surrounds another component" may refer to the component being at least partially peripherally adjacent to the periphery of the another component in a top view. In one embodiment, the first shielding component 125a may be located in a scribe line of the substrate 110a, but is not limited thereto. In one embodiment, the signal pattern 122a and the first shielding component 125a are mutually isolated or have a spacing therebetween, meaning that the signal pattern 122a and the first shielding component 125a have no contact and no connection. In one embodiment, the signal pattern 122a may be electrically connected to the first shielding component 125a. In the present disclosure, the shielding component may include a plurality of connecting portions C and a plurality of pad portions P, wherein the plurality of pad portions P are connected through the plurality of connecting portions C. In one embodiment, the pad portions P of the first shielding component 125a may capture electrostatic generated during processes and consume the electrostatic by damaging the pad portions P to prevent the electrostatic from causing damage to, for example, the signal pattern 122a. In one embodiment, the connecting portions C of the first shielding component 125a may serve as guidance for electrostatic dissipation direction. In one embodiment, in a top view, the shape of the pad portions P is, for example, circular shape, while the shape of the connecting portions C is, for example, strip shape or linear shape. In one embodiment, in a top view, the pad portions P may be polygonal or any other pattern that easily captures free ions in the environment. In one embodiment, the width (for example, the maximum width) of each pad portion P is D, while the width (for example, the maximum width) of each connecting portion C is d, and D≧5d. In one embodiment, the plurality of pad portions P may be combined with different dimensions. In one embodiment, the width d of the connecting portions C is ≤20 micrometers. In brief, the first shielding component 125a of the shielding component 124a may be used to capture electrostatic inside the substrate 110a to prevent or avoid damage to, for example, the signal pattern 122a.

Please refer to FIG. 1 again, the second shielding component 127a of the shielding component 124a is disposed in the second region R2 of the substrate 110a, for example, a peripheral region, and is mutually isolated from the first shielding component 125a. The second shielding component 127a has a sharp-angled pattern at one end adjacent to the edge E of the substrate 110a, which may significantly enhance electric field intensity, causing nearby air ionization and gas discharge, the above phenomenon is called corona discharge. That is, the gas discharge phenomenon caused by air ionization near the sharp-angled tip. Since the second shielding component 127a is configured adjacent to the edge E of the substrate 110a, it may guide ions to release from the first region R1 toward the second region R2 with the sharp-angled pattern to prevent or avoid damage to, for example, the signal pattern 122a due to electrostatic. In brief, the distance G between the second shielding component 127a and the edge E of the substrate 110a is, for example, less than 1000 micrometers to guide ion release out of the substrate 110a.

To improve electrostatic protection effect, in one implementation, the back surface of the substrate 110a may also be coated with, for example, indium tin oxide (ITO), which may improve the conductivity of the substrate 110a to prevent electrostatic accumulation. That is, the substrate 110a may dissipate electrostatic through indium tin oxide with larger region. In one implementation, indium tin oxide may also be coated on both front and back surfaces of the substrate 110a. In one implementation, metal ions may be doped in the indium tin oxide, which may release electrostatic generated by friction during process. In one implementation, some metal blocks without electrical properties may also be set around the signal pattern 122a, and connected to ground layer, power layer or other layers having larger metal pads through conductive through holes to release electrostatic during process.

In one implementation, for convenient assembly alignment, alignment patterns may be disposed at at least two corners of the substrate 110a and/or at edges corresponding to electronic units for subsequent assembly, meaning that the alignment patterns may be located in the second region R2 and mutually isolated from the second shielding component 127a. In one implementation, the alignment patterns may be appropriate patterns. In one implementation, the overall length of each alignment pattern may be 0.5 millimeters to 3 millimeters, and the width of each alignment pattern may be 10 micrometers to 100 micrometers.

In brief, since the package device 100a has the first shielding component 125a and second shielding component 127a that are isolated from each other on the substrate 110a, and along the direction perpendicular to the normal direction N of the substrate 110a, the dimension of the second shielding component 127a gradually increases with increasing distance from the edge E of the substrate 110a, thereby achieving electrostatic protection effect, making the package device 100a of this implementation have better yield or reliability.

Please refer to FIG. 1 and FIG. 2 simultaneously, region A in FIG. 1 may be region A1, which exemplifies an interposer unit, may have a first region R3 and a second region R4 surrounding the first region R3, and the shielding component ESD1 may be disposed in the second region R4. In one implementation, the shielding component ESD1 exemplifies a continuous ring structure, surrounding the periphery of the first region R3.

Please refer to FIGS. 1 and 3 simultaneously, region A in FIG. 1 may be region A2, which exemplifies a strip or middle or rear assembly unit of substrate, which at least includes RDL or through glass via (TGV) substrate unit, may have a first region R3 and a second region R4 surrounding the first region R3, and multiple shielding components ESD2 are disposed in the second region R4 separated from each other.

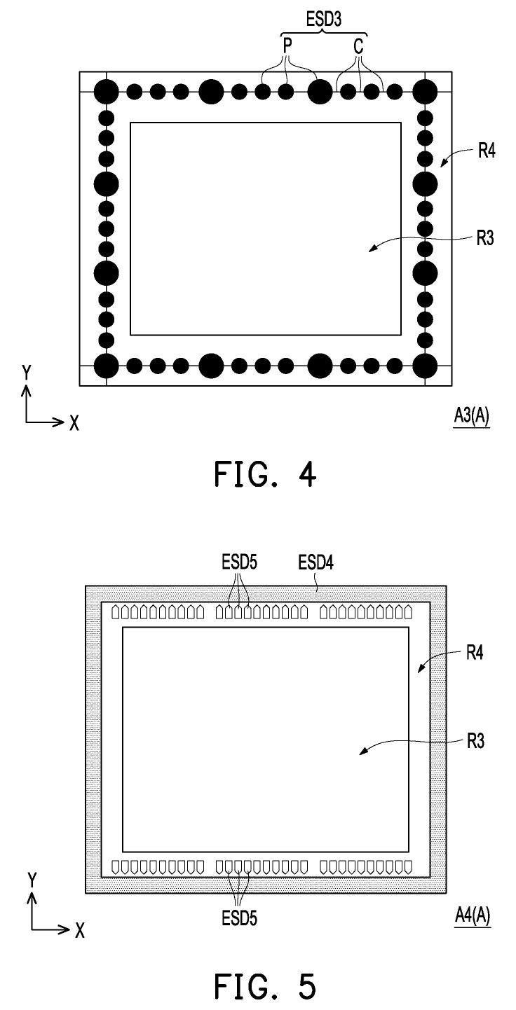

Please refer to FIGS. 1 and 4 simultaneously, region A in FIG. 1 may be region A3, which exemplifies an interposer or strip unit, may have a first region R3 and a second region R4 surrounding the first region R3, and the shielding component ESD3 is disposed in the second region R4 or in a ring shape to surround the first region R3. In one implementation, the pad portion P of the shielding component ESD3 may capture electrostatic generated during process, and consume the electrostatic through damaging the pad portion P, and the connecting portion C of the shielding component ESD3 may serve as guidance for electrostatic dissipation direction.

Please refer to FIGS. 1 and 5 simultaneously, region A in FIG. 1 may be region A4, which exemplifies a strip or interposer unit, may have a first region R3 and a second region R4 surrounding the first region R3, and the shielding component ESD4 and multiple shielding components ESD5 are disposed in the second region R4. In one implementation, in a top view, the shielding component ESD4 exemplifies a continuous ring structure, surrounding the periphery of the first region R3, and the shielding components ESD5 are located between the shielding component ESD4 and the first region R3. In one implementation, the shielding components ESD5 are arranged symmetrically in upper and lower positions in the X-axis direction.

In brief, in addition to the shielding component 124a that may be disposed on a large panel (such as substrate 110a), shielding components (such as shielding components ESD1~ESD5) may also be disposed in the peripheral region (i.e., the second region R4) of a small panel (such as region A), which may effectively prevent or avoid damage to, for example, the signal pattern 122a due to electrostatic, and may have better electrostatic protection effect.

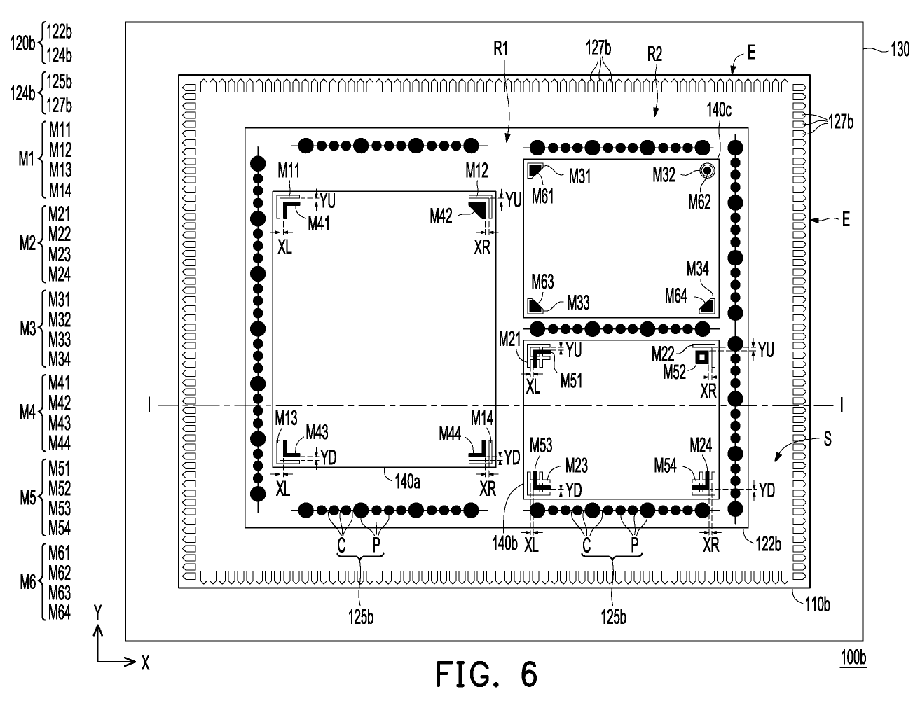

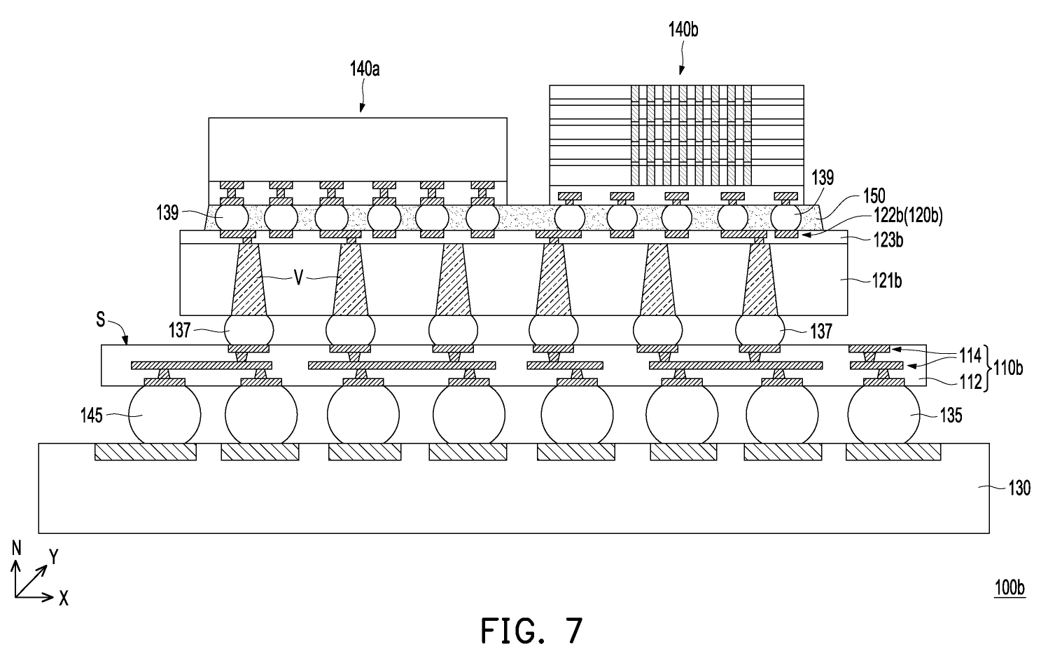

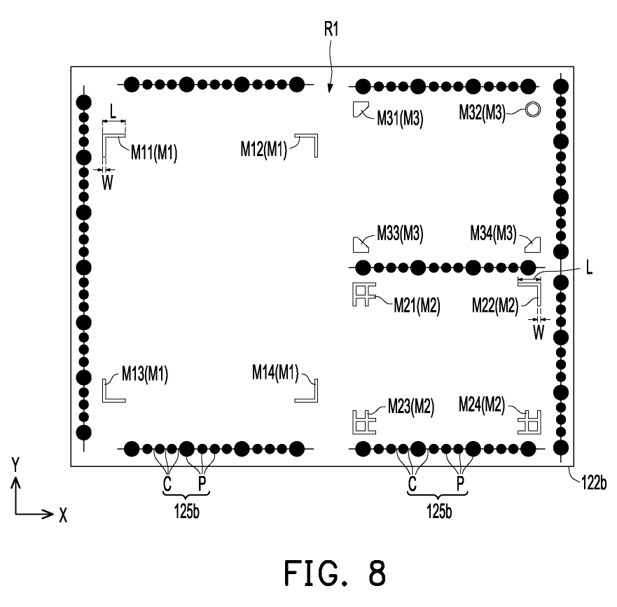

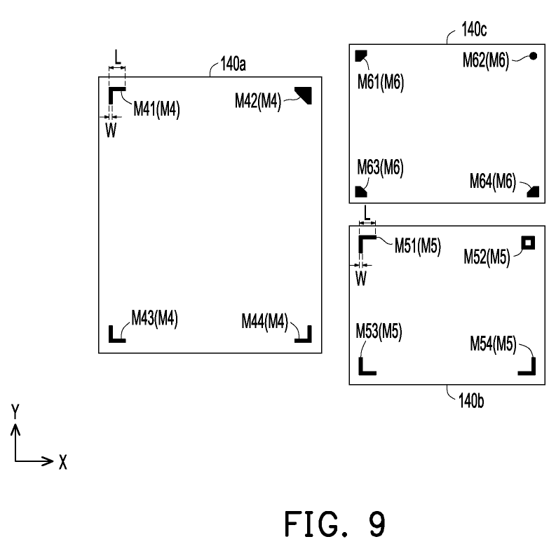

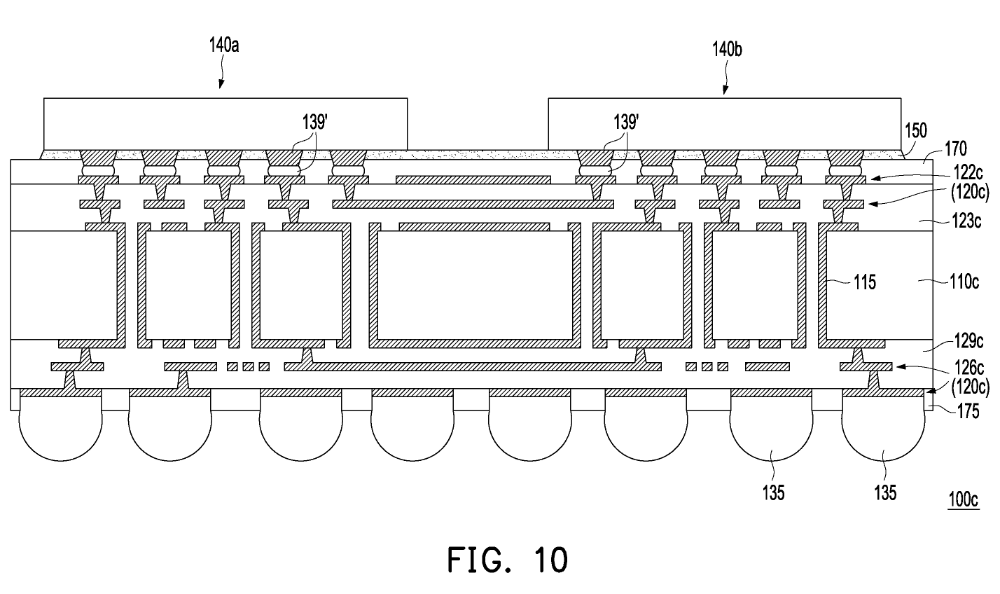

FIG. 6 is a top view of a package device according to another implementation of the present disclosure. FIG. 7 is a cross-sectional view along line I-I in FIG. 6. FIG. 8 is a top view of the redistribution layer structure or through glass via substrate in FIG. 6. FIG. 9 is a top view of the electronic unit in FIG. 6. FIG. 10 is a cross-sectional view of a package device according to another implementation of the present disclosure.

Please refer to FIGS. 6 and 7 simultaneously, the package device 100b further includes a carrier 130, an electronic unit 140a, an electronic unit 140b, and an electronic unit 140c in addition to the substrate 110b and the metal structure 120b. In detail, the substrate 110b is structurally and electrically connected to the carrier 130 through connecting elements 135, wherein the substrate 110b may exemplify a redistribution substrate, including at least one dielectric layer 112 and at least one metal layer 114 alternately stacked along the normal direction N of the substrate 110b. In one implementation, the material of the dielectric layer 112 exemplifies polyimide, Ajinomoto build-up film (ABF), silicon dioxide (SiO₂), or silicon nitride (SiN_{X}), but is not limited thereto. In one implementation, the carrier 130 may exemplify a printed circuit board, but is not limited thereto. In one implementation, the connecting elements 135 may exemplify tin, nickel, gold, silver, palladium, copper, gallium, the aforementioned alloys, or combinations thereof, but are not limited thereto. In one implementation, the connecting elements 135 exemplify solder balls, but are not limited thereto.

The substrate 110b has a first region R1 and a second region R2 surrounding the first region R1. The metal structure 120b is disposed on the substrate 110b and includes a signal pattern 122b and a shielding component 124b. The shielding component 124b includes a first shielding component 125b and a second shielding component 127b. The signal pattern 122b and the first shielding component 125b are disposed in the first region R1, while the second shielding component 127b is disposed in the second region R2. The first shielding component 125b and the second shielding component 127b are isolated from each other. Along a direction perpendicular to the normal direction N of the substrate 110b, the dimension of the second shielding component 127b gradually increases with increasing distance from the edge E of the substrate 110b.

In one implementation, the signal pattern 122b is formed on a glass substrate 121b having through holes V, and a dielectric layer 123b covers the signal pattern 122b, wherein the glass substrate 121b is structurally and electrically connected to the substrate 110b through connecting elements 137. In one implementation, the through hole V is a TGV. In one implementation, at least a portion of the first shielding component 125b is disposed in the through hole V. In one implementation, the second shielding component 127b is disposed on the surface S of the substrate 110b. In one implementation, the material of the dielectric layer 123b is similar to the material of the dielectric layer 112. In one implementation, the material of the connecting elements 137 is similar to the material of the connecting elements 135, but is not limited thereto. In one implementation, the connecting elements 137 exemplify solder balls, but are not limited thereto. In one implementation, the design of the first shielding component 125b may be similar to the first shielding component 125a. In one implementation, there are no other patterns having circuit functions on the discharge path of the second shielding component 127b. In this disclosure, in a top view, the patterns of the second shielding component 127b, shielding components ESD2, ESD5 exemplify a shield shape having a sharp-angled pattern at one end, which may be regarded as point discharge patterns for guiding ion release.

Electronic units 140a, 140b, and 140c are disposed on the signal pattern 122b of the metal structure 120b, and are structurally and electrically connected to the signal pattern 122b through connecting elements 139. In one implementation, the electronic units and the shielding components are staggered or do not overlap with each other. In one implementation, the electronic units 140a, 140b, and 140c may exemplify passive components, active components, or combinations thereof, such as semiconductor structures, silicon photonic chips, capacitors, resistors, inductors, variable capacitors, filters, diodes, transistors, sensors, micro-electro-mechanical system (MEMS) components, liquid crystal chips, etc., but are not limited thereto. In one implementation, the material of the connecting elements 139 is similar to the material of the connecting elements 135, but is not limited thereto. In one implementation, the connecting elements 139 exemplify solder balls, but are not limited thereto.

Additionally, the package device 100b of this implementation further includes an adhesive layer 150 disposed between the electronic units 140a, 140b, and 140c and the signal pattern 122b, wherein the adhesive layer 150 at least covers the connecting elements 139. In one implementation, the adhesive layer 150 may exemplify an underfill layer that may directly contact the active surfaces of the electronic units 140a, 140b, and 140c and the surface of the signal pattern 122b relatively distant from the glass substrate 121b, and fill the space between two adjacent connecting elements 139. In one implementation, the adhesive layer 150 is used for protecting the connecting elements 139 or ensuring the bonding between the electronic units 140a, 140b, and 140c and the signal pattern 122b. In one implementation, the material of the adhesive layer 150 may exemplify resin, epoxy resin, or molding compound, but is not limited thereto.

Next, please refer to FIG. 6, FIG. 8, and FIG. 9 simultaneously. In order to improve the assembly accuracy of the electronic units, alignment patterns may be included in the signal pattern 122b and at least one of the electronic units 140a, 140b, and 140c. That is to say, the alignment patterns may be set only on the signal pattern 122b, or only on the electronic units 140a, 140b, and 140c, or on both the signal pattern 122b and the electronic units 140a, 140b, and 140c.

In one implementation, the signal pattern 122b may include first alignment pattern M1, first alignment pattern M2, and first alignment pattern M3. The electronic unit 140a may include second alignment pattern M4, the electronic unit 140b may include second alignment pattern M5, and the electronic unit 140c includes second alignment pattern M6. The first alignment pattern M1 may be disposed at the four corners corresponding to the electronic unit 140a to be subsequently assembled, and corresponds to the second alignment pattern M4 of the electronic unit 140a. Furthermore, the first alignment pattern M1 of the signal pattern 122b includes alignment patterns M11~M14, while the second alignment pattern M4 of the electronic unit 140a includes alignment patterns M41~M44. In one implementation, in a top view, the alignment patterns M11~M14 and the alignment patterns M41~M44 respectively have length L and width W, where the length L is, for example, 0.1 millimeters to 0.5 millimeters, and the width W is, for example, 5 micrometers to 50 micrometers. When the electronic unit 140a is assembled on the signal pattern 122b, the alignment patterns M41~M44 will respectively align with the alignment patterns M11~M14 and be positioned inside them. For example, between the alignment pattern M41 and the alignment pattern M11, there is a parallel displacement XL on the left side of the X-axis and a parallel displacement YU on the upper side of the Y-axis; between the alignment pattern M42 and the alignment pattern M12, there is a parallel displacement XR on the right side of the X-axis and a parallel displacement YU on the upper side of the Y-axis; between the alignment pattern M43 and the alignment pattern M13, there is a parallel displacement XL on the left side of the X-axis and a parallel displacement YD on the lower side of the Y-axis; and between the alignment pattern M44 and the alignment pattern M14, there is a parallel displacement XR on the right side of the X-axis and a parallel displacement YD on the lower side of the Y-axis. Here, the parallel displacement may also be regarded as the gap between two alignment patterns. The parallel displacements XL, XR, YU, and YD may be compared with the width W to quickly visually determine whether the electronic unit 140a has bonding displacement from the predetermined position on the signal pattern 122b. Since the geometric pattern of the alignment pattern M42 is different from the alignment patterns M41 and M43~M44, it may serve as a foolproof pattern for alignment, which may improve assembly accuracy. In one implementation, the parallel displacements XL, XR, YU, and YD may be defined as a process window, which makes specification determination easier. In one implementation, the two lines defining the parallel displacement should remain parallel to the metric silicon die (Si-die) and not rotate, that is, the angles of these two lines should be consistent with the rotation angle of the electronic unit 140a. That is to say, alignment patterns may be selectively set on the redistribution structure layer and/or the electronic unit, thereby improving the alignment accuracy between the electronic unit and the redistribution structure layer.

Similarly, the first alignment pattern M2 of the signal pattern 122b may be disposed at the four corners corresponding to the electronic unit 140b to be subsequently assembled, and corresponds to the second alignment pattern M5 of the electronic unit 140b. Furthermore, the first alignment pattern M2 of the signal pattern 122b includes alignment patterns M21~M24, while the second alignment pattern M5 of the electronic unit 140b includes alignment patterns M51~M54. In one implementation, in a top view, the alignment patterns M21~M24 and the alignment patterns M51~M54 respectively have length L and width W, where the length L is, for example, 0.1 millimeters to 0.5 millimeters, and the width W is, for example, 5 micrometers to 50 micrometers. When the electronic unit 140b is assembled on the signal pattern 122b, the alignment patterns M51~M54 will respectively align with the alignment patterns M21~M24 and be positioned inside them. For example, between the alignment pattern M51 and the alignment pattern M21, there is a parallel displacement XL on the left side of the X-axis and a parallel displacement YU on the upper side of the Y-axis; between the alignment pattern M52 and the alignment pattern M22, there is a parallel displacement XR on the right side of the X-axis and a parallel displacement YU on the upper side of the Y-axis; between the alignment pattern M53 and the alignment pattern M23, there is a parallel displacement XL on the left side of the X-axis and a parallel displacement YD on the lower side of the Y-axis; and between the alignment pattern M54 and the alignment pattern M24, there is a parallel displacement XR on the right side of the X-axis and a parallel displacement YD on the lower side of the Y-axis. Since the geometric pattern of the alignment pattern M52 is different from the alignment patterns M51 and M53~M54, it may serve as a foolproof pattern for alignment, or may reduce assembly error issues. In one implementation, the parallel displacements XL, XR, YU, and YD may be compared with the width W to quickly visually determine whether the electronic unit 140b has bonding displacement from the predetermined position on the signal pattern 122b.

Additionally, the alignment pattern may also be a combination of geometric patterns. The first alignment pattern M3 of the signal pattern 122b may be disposed at the four corners corresponding to the electronic unit 140c to be subsequently assembled, and corresponds to the second alignment pattern M6 of the electronic unit 140c. Furthermore, the first alignment pattern M3 of the signal pattern 122b includes alignment patterns M31~M34, while the second alignment pattern M6 of the electronic unit 140c includes alignment patterns M61~M64. When the electronic unit 140c is assembled on the signal pattern 122b, the alignment patterns M61~M64 will respectively align with the alignment patterns M31~M34 and be positioned inside them. Since the geometric pattern of the alignment pattern M62 is different from the alignment pattern M61 and alignment patterns M63~M64, the assembly accuracy may be improved. In one implementation, the setting of the alignment pattern may enable rework of a single chip in a multi-chip package before assembly, or fine-tune the placement position of the chip before assembly.

In one implementation, please refer to FIG. 6, FIG. 7 and FIG. 10 simultaneously, the substrate 110c of the package device 100c may include through holes 115, wherein the material of the substrate 110c is, for example, glass. The substrate 110c, same as the substrate 110b, may have a first region R1 and a second region R2 surrounding the first region R1. The metal structure 120c is disposed on the substrate 110c, and same as the metal structure 120b includes the signal pattern 122b and the shielding component 124b. Furthermore, the metal structure 120c of this implementation may further include a signal pattern 126c, wherein the signal pattern 122c and the signal pattern 126c are respectively positioned on opposite sides of the substrate 110c, and the signal pattern 122c and the dielectric layer 123c are alternately arranged, while the signal pattern 126c and the dielectric layer 129c are alternately arranged, wherein the signal pattern 124c and the signal pattern 126c are respectively electrically connected with the through hole 115. In one implementation, the material of the dielectric layers 123c, 129c is similar to the material of the dielectric layer 112, but is not limited thereto.

The package device 100c of this implementation further includes a solder mask layer 170 and a solder mask layer 175, wherein the solder mask layer 170 covers the signal pattern 122c and exposes a portion of the signal pattern 122c, while the solder mask layer 175 covers the signal pattern 126c and exposes the signal pattern 126c. The electronic unit 140a, the electronic unit 140b and the electronic unit 140c are disposed on the signal pattern 122c of the metal structure 120c, and are structurally and electrically connected with the signal pattern 122c through connecting elements 139'. In one implementation, the connecting element 139' is, for example, eutectic solder, nickel, gold, copper, gallium, alloy, combinations of the above or other suitable materials, but is not limited thereto. The signal pattern 126c may be electrically connected with external circuits through connecting elements 135.

In one implementation, the package device may include a carrier, an interposer substrate (such as a through silicon via (TSV) substrate or a glass through hole substrate), a redistribution layer structure, an electronic unit, a first solder ball to a third solder ball. The interposer substrate is structurally and electrically connected to the carrier through the first solder ball. The redistribution layer structure is disposed on a surface of the interposer substrate relatively away from the carrier, and the electronic unit is structurally and electrically connected to the redistribution layer structure through the second solder ball. The carrier may be electrically connected with external circuits through the third solder ball. In one implementation, the redistribution layer structure is in a central region of the interposer substrate, and a first shielding component may be set around the redistribution layer structure, while a second shielding component may be set in a surrounding region of the interposer substrate, thereby achieving electrostatic protection.

In one implementation, in the manufacturing process of the package device, first, a redistribution layer structure is formed on a glass substrate. The redistribution layer structure includes first alignment patterns at four corners, which may be used for coarse alignment, forming an encapsulant, forming metal pillars/bumps, forming solder balls and singulation cutting processes. Next, second alignment patterns are formed at four corners of the electronic unit for fine alignment, which may ensure alignment accuracy of the electronic unit during bonding. Next, through the first alignment patterns, metal pillars are formed on the redistribution layer structure, and through the second alignment patterns, the electronic unit is assembled on the redistribution layer structure. Next, an encapsulant is formed through the first alignment patterns to encapsulate the electronic unit and the metal pillars. Next, a grinding process may be selectively performed to remove a portion of the encapsulant and expose a back surface of the electronic unit and one end of the metal pillars. Thereafter, a thermal conductive layer may be formed on the back surface of the electronic unit and one end of the metal pillars. In one implementation, a laser drilling process may be performed on the encapsulant, and a thermal conductive layer is formed on the encapsulant and extends into the holes to connect with the back surface of the electronic unit and one end of the metal pillars. Finally, the glass substrate may be removed to expose the redistribution layer structure, and solder balls are formed on the redistribution layer structure to complete the fabrication of the package device.

In one implementation, in the manufacturing process of the package device, first, a redistribution layer structure using photosensitive polyimide is formed as a dielectric layer on a glass substrate. Next, a dielectric layer having multiple openings is formed. Next, conductive structures are formed in the openings and extend onto the build-up layer. Next, the above structure is flipped onto a temporary carrier, and the glass substrate is removed to expose the redistribution layer structure. Next, the electronic unit is assembled to the redistribution layer structure, and an encapsulation process is performed on the electronic unit. Thereafter, the temporary carrier is removed, and solder balls are formed on the conductive structures to complete the package device. The dielectric layer may be multi-layered, wherein the openings of these stacked dielectric layers are connected to each other, and the dimensions of the openings become smaller as they distance from the electronic unit.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. A package device, comprising:
a substrate having a first region and a second region surrounding the first region; and
a metal structure disposed on the substrate and comprising a signal pattern and a shielding component, the shielding component comprising a first shielding component and a second shielding component, the signal pattern and the first shielding component being disposed in the first region, and the second shielding component being disposed in the second region, the first shielding component and the second shielding component being isolated from each other, wherein along a direction perpendicular to a normal direction of the substrate, a dimension of the second shielding component gradually increases with increasing distance from an edge of the substrate.

2. The package device as claimed in claim 1, wherein the substrate comprises a through hole, and at least a portion of the first shielding component is disposed in the through hole.

3. The package device as claimed in claim 2, wherein the second shielding component is disposed on a surface of the substrate.

4. The package device as claimed in claim 2, wherein a material of the substrate comprises glass.

5. The package device as claimed in claim 1, wherein the signal pattern and the first shielding component are isolated from each other.

6. The package device as claimed in claim 1, further comprising:
an electronic unit disposed on the signal pattern of the metal structure and electrically connected to the signal pattern.

7. The package device as claimed in claim 6, wherein the electronic unit and the shielding component do not overlap with each other.

8. The package device as claimed in claim 6, further comprising:
a connecting element, the electronic unit being electrically connected to the signal pattern through the connecting element.

9. The package device as claimed in claim 8, further comprising:
an adhesive layer disposed between the electronic unit and the signal pattern, wherein the adhesive layer at least covers the connecting element.

10. The package device as claimed in claim 6, wherein at least one of the signal pattern and the electronic unit comprises an alignment pattern.

11. The package device as claimed in claim 10, wherein the signal pattern comprises a first alignment pattern, the electronic unit comprises a second alignment pattern, and there is a parallel displacement between the first alignment pattern and the second alignment pattern.

12. The package device as claimed in claim 10, wherein a length of the alignment pattern is in a range of 0.1 millimeters to 0.5 millimeters.

13. The package device as claimed in claim 10, wherein a width of the alignment pattern is in a range of 5 micrometers to 50 micrometers.

14. The package device as claimed in claim 1, wherein the first shielding component comprises a plurality of connecting portions and a plurality of pad portions, the plurality of pad portions are connected through the plurality of connecting portions, and each of the plurality of pad portions has a dimension of D, while each of the plurality of connecting portions has a dimension of d, and D≧5d.

15. The package device as claimed in claim 14, wherein a shape of each of the plurality of pad portions comprises a circular shape, and a shape of each of the plurality of connecting portions comprises a strip shape or a linear shape.

16. The package device as claimed in claim 1, wherein a distance between the second shielding component and the edge of the substrate is less than 1000 micrometers.

17. The package device as claimed in claim 1, wherein the first region is rectangular, and the second region is annular.

18. The package device as claimed in claim 1, wherein the shielding component of the metal structure has no electrical properties.

19. The package device as claimed in claim 1, wherein the substrate comprises an alignment pattern, the alignment pattern being located in the second region and isolated from the second shielding component.

20. The package device as claimed in claim 19, wherein a length of the alignment pattern is in a range of 0.5 millimeters to 3 millimeters, and a width of the alignment pattern is in a range of 10 micrometers to 100 micrometers.
